(19) United States
(12) Patent Application Publication
(10) Pub. No.: US 2024/0250107 A1
(43) Pub. Date: Jul. 25, 2024

(54) IMAGING DEVICE

(71) Applicant: Panasonic Intellectual Property Management Co., Ltd., Osaka (JP)

(72) Inventors: TAKAYUKI NISHITANI, Osaka (JP); YOSHIHIRO SATO, Osaka (JP)

(21) Appl. No.: 18/625,169

(22) Filed: Apr. 2, 2024

Related U.S. Application Data
(63) Continuation of application No. PCT/JP2022/028864, filed on Jul. 27, 2022.

(30) Foreign Application Priority Data
Oct. 27, 2021 (JP) 2021-175818

(51) Int. Cl. H01L 27/146; H04N 25/60; H04N 25/77

(52) U.S. Cl. CPC H01L 27/14636; H01L 27/14643; H01L 27/14614; H04N 25/60; H04N 25/77

(57) ABSTRACT

An imaging device includes: a semiconductor substrate; a plurality of pixels arrayed in a first direction on the semiconductor substrate; and a first signal line positioned above the semiconductor substrate. Each of the plurality of pixels includes: a photoelectric converter that converts light into signal charges; a transistor that includes a gate electrically coupled to the first signal line; and a capacitive element. In a first pixel of the plurality of pixels, at least a part of the transistor overlaps the capacitive element in plan view, and the capacitive element does not overlap the entire width of the first signal line in plan view.

### BACKGROUND

### 1. Technical Field

The present disclosure relates to an imaging device.

### 2. Description of the Related Art

Digital cameras and other devices use image sensors. For example, image sensors include charge coupled device (CCD) image sensors, complementary metal oxide semiconductor (CMOS) image sensors, and the like. Image sensors can be used to constitute an imaging device. In an imaging device according to an example, photodiodes are provided in a semiconductor substrate. In an imaging device according to another example, a photoelectric conversion film is laid above a semiconductor substrate.

Japanese Patent Unexamined Application No. 2016-105468 publication discloses an imaging device including photodiodes. Japanese Patent Unexamined Application No. 2018-195803 publication discloses an imaging device including a photoelectric conversion film. In the imaging devices disclosed in Japanese Patent Unexamined Application Nos. 2016-105468 and 2018-195803 publications, each pixel includes a capacitive element. The entire disclosure of Japanese Patent Unexamined Application No. 2018-195803 is incorporated herein by reference.

### SUMMARY

One non-limiting and exemplary embodiment provides an imaging device capable of implementing high-speed imaging.

In one general aspect, the techniques disclosed here feature an imaging device including: a semiconductor substrate; a plurality of pixels arrayed in a first direction on the semiconductor substrate; and a first signal line positioned above the semiconductor substrate, in which each of the plurality of pixels includes: a photoelectric converter that converts light into signal charges; a transistor that includes a gate electrically coupled to the first signal line; and a capacitive element, in a first pixel of the plurality of pixels, at least a part of the transistor overlaps the capacitive element in plan view, and the capacitive element does not overlap the entire width of the first signal line in plan view.

The aforementioned aspects of the present disclosure are suitable for providing an imaging device capable of implementing high-speed imaging.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram schematically illustrating an exemplary circuit configuration of an imaging device according to Embodiment 1;

FIG. 2 is a diagram illustrating an exemplary circuit configuration of a pixel according to Embodiment 1;

FIG. 3 is a schematic plan view of a layout example of some elements of the pixel according to Embodiment 1;

FIG. 4 is a schematic cross-sectional view taken along a line IV-IV illustrated in FIG. 3;

FIG. 5 is a diagram schematically illustrating an exemplary circuit configuration of a pixel using a photodiode;

FIG. 6 is a schematic diagram for explaining plural pixels according to Embodiment 1;

FIG. 7 is a schematic diagram for explaining plural pixels according to a modification;

FIG. 8 is a plan view for explaining the direction in which a signal line extends;

FIG. 9 is a plan view for explaining the direction in which a signal line extends;

FIG. 10 is a plan view for explaining the direction in which a signal line extends;

FIG. 11 is a plan view for explaining dimensions of a capacitive element;

FIG. 12 is a plan view for explaining the maximum length of the capacitive element;

FIG. 13 is a plan view for explaining the maximum length of the capacitive element;

FIG. 14 is a schematic plan view of a layout example of some traces and some elements of a pixel according to Embodiment 1;

FIG. 15 is a cross-sectional view schematically illustrating a cross section of an imaging device according to a first reference example;

FIG. 16 is a schematic cross-sectional view schematically illustrating a cross section of an imaging device according to a second reference example;

FIG. 17 is a schematic cross-sectional view schematically illustrating a cross section of the imaging device according to Embodiment 1;

FIG. 18 is a cross-sectional view illustrating a capacitive element having a trench structure;

FIG. 19 is a plan view schematically illustrating a layout example of some traces and some elements of a pixel according to Embodiment 2;

FIG. 20 is a plan view schematically illustrating a layout example of some traces and some elements of a pixel according to Embodiment 3;

FIG. 21 is a plan view schematically illustrating a layout example of some traces and some elements of a pixel according to Embodiment 4;

FIG. 22 is a plan view schematically illustrating a layout example of some traces and some elements of a pixel according to Embodiment 5;

FIG. 23 is a plan view schematically illustrating a layout example of some traces and some elements of a pixel according to another embodiment; and

FIG. 24 is a plan view schematically illustrating a layout example of some traces and some elements of a pixel according to still another embodiment.

### DETAILED DESCRIPTIONS

Underlying Knowledge Forming Basis of the Present Disclosure

An imaging device according to an example includes plural pixels arrayed in a predetermined direction. Each pixel includes plural transistors. Each transistor is coupled to a signal line. Each signal line extends from a peripheral circuit in a predetermined direction across some pixels and is coupled to a corresponding transistor of each pixel to transmit a control signal to the corresponding transistor. Each pixel includes a capacitive element. The capacitive element is used to expand the dynamic range, implement noise cancellation, and the like.

The capacitive element has a large capacitance value in some cases. In such a case, the capacitive element tends to occupy a large proportion of the area of each pixel in plan view. The capacitive element therefore tends to overlap a signal line in plan view. According to the inventors' consideration, such overlap increases parasitic capacitance between the signal line and the capacitive element and delays the control signal flowing through the signal line. This can reduce the imaging speed.

The inventors therefore devised the layout of the capacitive element and a signal line and considered a configuration capable of implementing high-speed imaging.

### Outline of Aspects According to Present Disclosure

An imaging device according to a first aspect of the present disclosure includes:
a semiconductor substrate;
a plurality of pixels arrayed in a first direction on the semiconductor substrate; and
a first signal line positioned above the semiconductor substrate, in which
each of the plurality of pixels includes:
   a photoelectric converter that converts light into signal charge;
   a transistor that includes a gate electrically coupled to the first signal line; and
   a capacitive element,
in a first pixel among the plurality of pixels,
at least a part of the transistor overlaps the capacitive element in plan view, and
the capacitive element does not overlap the entire width of the first signal line in plan view.

The technique according to the first aspect is suitable for providing an imaging device capable of implementing high-speed imaging.

According to a second aspect of the present disclosure, for example, in the imaging device according to the first aspect,
the gate of the transistor of the first pixel may include a first portion not overlapping the capacitive element in plan view, and
the first portion of the transistor of the first pixel may be electrically coupled to the first signal line.

The configuration of the second aspect is an example of the configuration coupling a signal line and the gate of the transistor corresponding to the signal line.

According to a third aspect of the present disclosure, for example, the imaging device according to the second aspect may further include a via in contact with the first portion, and
the first portion of the transistor may be electrically coupled to the first signal line through the via.

The third aspect is an example of the configuration coupling a signal line and the gate of the transistor corresponding to the signal line.

According to a fourth aspect of the present disclosure, the imaging device according to any one of the first to third aspects may further include a branch signal line,
the branch signal line may branch off from the first signal line and extend,
the direction in which the branch signal line extends may be different from the direction in which the first signal line extends in plan view, and
the first signal line may be electrically coupled to the transistor of the first pixel through the branch signal line.

The configuration of the fourth aspect is an example of the configuration coupling a signal line and the gate of the transistor corresponding to the signal line.

According to a fifth aspect of the present disclosure, for example, the imaging device according to any one of the first to fourth aspects,
the capacitive element of the first pixel does not need to overlap half or more than half of the line width of the first signal line in plan view.

The technique according to the fifth aspect is suitable for providing an imaging device capable of implementing high-speed imaging.

According to a sixth aspect of the present disclosure, for example, in the imaging device according to any one of the first to fifth aspects,
the first signal line does not need to overlap the capacitive element of the first pixel in plan view.

The technique according to the sixth aspect is suitable for providing an imaging device capable of implementing high-speed imaging.

According to a seventh aspect of the present disclosure, for example, the imaging device according to any one of the first to sixth aspects may further include a plurality of wiring layers positioned above the semiconductor substrate,
the plurality of wiring layers may include a first wiring layer and a second wiring layer that are adjacent to each other,
the capacitive element may be structured using the first wiring layer, and
the first signal line may be included in the second wiring layer.

When the capacitive element is structured using one of the wiring layers adjacent to each other and the other wiring layer includes a signal line like the seventh aspect, large parasitic capacitance can be produced between the signal line and the capacitive element. The parasitic capacitance being large means that the effect of minimizing the parasitic capacitance based on the planar layout of the signal line and capacitive element according to the first aspect can be easily exerted. That is, this planar layout easily contributes to high-speed imaging.

According to an eighth aspect of the present disclosure, for example, in the imaging device according to any one of the first to seventh aspects,
the maximum length of the capacitive element of the first pixel in the first direction may be greater than one third of the length of the first pixel in the first direction in plan view.

The signal line is electrically coupled to the individual pixels arrayed in the first direction. When the maximum length of the capacitive element in the first direction is as large as that of the eighth aspect, the parasitic capacitance between the signal line and the capacitive element can be large. The parasitic capacitance being large means that the effect of minimizing the parasitic capacitance based on the planar layout of the signal line and the capacitive element according to the first aspect can be easily exerted. That is, this planar layout easily contributes to high-speed imaging.

According to a ninth aspect of the present disclosure, for example, in the imaging device according to any one of the first to eighth aspects,
when the direction perpendicular to the thickness direction of the semiconductor substrate and the first direction is defined as a second direction, and
the maximum length of the capacitive element of the first pixel in the first direction may be greater than the maximum length of the capacitive element of the first pixel in the second direction.

The signal line is electrically coupled to the individual pixels arrayed in the first direction. In the configuration of the ninth aspect, the maximum length of the capacitive element in the first direction tends to be increased. The parasitic capacitance between the signal line and the capacitive element can therefore be increased. The parasitic capacitance being large means that the effect of minimizing the parasitic capacitance based on the planar layout of the signal line and the capacitive element according to the first aspect can be easily exerted. That is, this planar layout easily contributes to high-speed imaging.

According to a 10th aspect of the present disclosure, for example, in the imaging device according to any one of the first to ninth aspects,
the capacitive element of the first pixel may include a first electrode, a second electrode, and an insulating layer between the first electrode and the second electrode.

The capacitive element of the 10th aspect is an example of the configuration of the capacitive element.

According to an 11th aspect of the present disclosure, for example, in the imaging device according to the 10th aspect,
the first electrode and the second electrode may contain metal.

The capacitive element of the 11th aspect is an example of the configuration of the capacitive element.

According to a 12th aspect of the present disclosure, for example, in the imaging device according to any one of the first to 11th aspects,
the capacitive element of the first pixel may have the largest area in plan view of capacitive elements included in the first pixel.

The parasitic capacitance between the capacitive element having a large area as defined in the 12th aspect and the signal line can be large. The parasitic capacitance being large means that the effect of minimizing the parasitic capacitance based on the planar layout of the signal line and the capacitive element according to the first aspect can be easily exerted. That is, this planar layout easily contributes to high-speed imaging.

An imaging device according to a 13th aspect of the present disclosure includes:
a semiconductor substrate;
a plurality of pixels arrayed in a first direction on the semiconductor substrate; and
a first signal line positioned above the semiconductor substrate, in which
each of the plurality of pixels includes:
   a photoelectric converter that converts light into signal charges;
   a transistor that includes a gate electrically coupled to the first signal line; and
   a capacitive element,
in a first pixel of the plurality of pixels,
   at least a part of the transistor overlaps the capacitive element in plan view, and
the first signal line does not overlap half or more than half of the maximum length of the capacitive element in the first direction in plan view.

The technique according to the 13th aspect is suitable for providing an imaging device capable of implementing high-speed imaging.

An imaging device according to a 14th aspect of the present disclosure includes:
a vertical scanning circuit;
a semiconductor substrate;
a pixel provided in the semiconductor substrate; and
at least one signal line positioned above the semiconductor substrate, in which the pixel includes:
   a photoelectric converter that converts light into signal charges;
   a charge accumulation region that accumulates the signal charges;
   an amplification transistor that generates an electric signal corresponding to voltage of the charge accumulation region;
   a reset transistor that resets the voltage of the charge accumulation region; and
   an MIM capacitive element,
   at least one signal line includes a reset signal line electrically coupling the vertical scanning circuit and a gate of the reset transistor, and
   the reset signal line is spaced from the MIM capacitive element in plan view.

The technique according to the 14th aspect is suitable for providing an imaging device capable of implementing high-speed imaging. “The signal line is spaced from the MIM capacitive element in plan view.” means that the signal line does not have any overlap with the MIM capacitive element in plan view. “At least one signal line” in the 14th aspect may be a plurality of signal lines.

According to a 15th aspect of the present disclosure, for example, in the imaging device according to the 14th aspect,
the pixel may include a feedback transistor provided on a feedback route for negative feedback of the electric signal generated by the amplification transistor to the charge accumulation region,
the at least one signal line may include a feedback control line electrically coupling the vertical scanning circuit and a gate of the feedback transistor, and
the feedback control line may be spaced from the MIM capacitive element in plan view.

The technique according to the 15th aspect is suitable for providing an imaging device capable of implementing high-speed imaging.

According to a 16th aspect of the present disclosure, for example, in the imaging device according to the 14th or 15th aspect,
the pixel may include an address transistor that determines the timing to output the electric signal from the amplification transistor,
the at least one signal line may include an address signal line electrically coupling the vertical scanning circuit and a gate of the address transistor, and
the address signal line may be spaced from the MIM capacitive element in plan view.

The technique according to the 16th aspect is suitable for providing an imaging device capable of implementing high-speed imaging.

According to a 17th aspect of the present disclosure, for example, in the imaging device according to any one of the 14th to 16th aspects,
the pixel may include a transfer transistor provided between the photoelectric converter and the charge accumulation region,
the at least one signal line may include a transfer control line electrically coupling the vertical scanning circuit and a gate of the transfer tarnsistor of each of the plurality of pixels, and
the transfer control line may be spaced from the MIM capacitive element in plan view.

The technique according to the 17th aspect is suitable for providing an imaging device capable of implementing high-speed imaging.

The techniques according to the first to 17th aspects can be properly combined without any contradiction.

In embodiments, the terms, including “above”, “below”, “upper surface”, and “lower surface”, are just used to specify relative positions of members and do not intend to limit the orientation of the imaging device in use.

In the embodiments, “plan view” refers to a view in the thickness direction of the semiconductor substrate.

In the embodiments, the term “via” is used in some cases. In the embodiments, the “via” refers to a set of a via hole and a conductor within the via hole.

In the embodiments, the term “transistor control signal” is used in some cases. In the embodiments, the transistor control signal is a signal transmitted to a transistor and is a signal to control the transistor. In a typical example, the transistor control signal is transmitted to the gate, drain, or source of the transistor.

In the embodiments, the expression “element A is coupled to element B” is used in some cases. This expression implies a situation where a part or all of the element A is included in the element B”.

In the embodiments, the transistor's polarity and the impurity region's conductive type are illustrated by way of example. The transistor's polarity and the impurity region's conductive type may be inverted without any contradiction. To invert the transistor's polarity and the impurity region's conductive type, each element is adjusted properly.

In the embodiments, “coupled” and “electrically coupled” can be used interchangeably without any contradiction. In the embodiments, “gate” and “gate electrode” may be interchangeably used without any contradiction.

In the embodiments, the configuration of a pixel is described in some cases. The described configuration can appear in each pixel. In addition, the relationship between elements and signal lines of a pixel is described in some cases. The described relationship can appear in each pixel without any contradiction.

Hereinafter, the embodiments will be described in detail with reference to the drawings.

### Embodiment 1

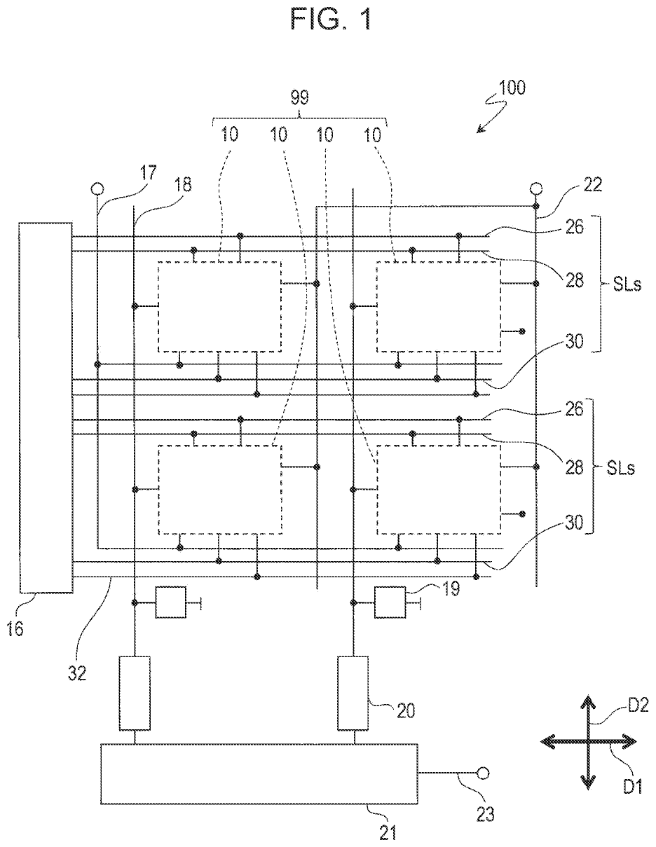

FIG. 1 is a diagram schematically illustrating an exemplary circuit configuration of an imaging device according to Embodiment 1. An imaging device 100 illustrated in FIG. 1 includes plural pixels 99 and peripheral circuits. The plural pixels 99 constitute a pixel region. The plural pixels 99 are structured using a semiconductor substrate. The semiconductor substrate is not limited to a substrate that is entirely made of a semiconductor. The semiconductor substrate may include a semiconductor layer and an insulating layer, and the surface of the semiconductor substrate where the pixel region is provided may be composed of the semiconductor layer. In FIG. 1 and other drawings, each pixel included in the plural pixels 99 is represented as a pixel 10.

In the example illustrated in FIG. 1, the plural pixels 99 are arrayed in a row direction and in a column direction. The row direction corresponds to the horizontal direction, and the column direction corresponds to the vertical direction. In the example illustrated in FIG. 1, the plural pixels 99 are two-dimensionally arrayed. The plural pixels 99 may be one-dimensionally arrayed. In other words, the imaging device 100 can be a line sensor. The number of the pixels 10 included in the imaging device 100 may be one.

Each pixel 10 is coupled to a power-supply line 22. The pixel 10 is supplied with one or more voltages through the power-supply line 22. This “one or more voltages” may be either “two or more voltages” or “two different voltages”. The pixel 10 includes a photoelectric converter. The photoelectric converter includes a photoelectric conversion film. The photoelectric conversion film is laid on the semiconductor substrate. The photoelectric converter is provided on the semiconductor substrate with a wiring layer interposed therebetween. As illustrated in FIG. 1, the imaging device 100 includes an accumulation control line 17, which applies the same constant voltage to all the photoelectric converters.

The peripheral circuits include a vertical scanning circuit 16, a load circuit 19, a column signal processing circuit 20, and a horizontal signal reading circuit 21. In the configuration illustrated in FIG. 1, the column signal processing circuit 20 and the load circuit 19 are provided for each column of the plural pixels 99, which are two-dimensionally arrayed. That is, in this example, the peripheral circuits include a plurality of the column signal processing circuits 20 and a plurality of the load circuits 19.

The vertical scanning circuit 16 is also referred to as a row scanning circuit. The vertical scanning circuit 16 is coupled to address signal lines 30 and reset signal lines 26. The vertical scanning circuit 16 can apply a predetermined voltage to the address signal lines 30 or the reset signal lines 26. The plural pixels 99 constitute plural rows. By applying the predetermined voltage, one of the rows is selected, and reading of signal voltage or resetting is executed for the pixels 10 belonging to the selected row. In the example illustrated in FIG. 1, the vertical scanning circuit 16 is also coupled to feedback control lines 28 and sensitivity adjustment lines 32.

The vertical scanning circuit 16 is able to supply a predetermined voltage to the plural pixels 99 through the sensitivity adjustment lines 32. In Embodiment 1, each pixel 10 includes one or more capacitive elements within the pixel.

The plural pixels 99 constitute plural columns. The pixels 10 belonging to each column are electrically coupled to the column signal processing circuit 20 corresponding to the column through the corresponding vertical signal line 18. The vertical signal line 18 is electrically coupled to the load circuit 19. The column signal processing circuits 20 are also referred to as row signal accumulation circuits. Each column signal processing circuit 20 performs noise reduction signal processing, analog-digital conversion (AD conversion), and the like. The noise reduction signal processing is, for example, correlated double sampling. The plural column signal processing circuits 20 provided corresponding to the respective rows are electrically coupled to the horizontal signal reading circuit 21. The horizontal signal reading circuit 21 is also referred to as a column scanning circuit. The horizontal signal reading circuit 21 sequentially reads signals from the plural column signal processing circuits 20 into a horizontal common signal line 23.

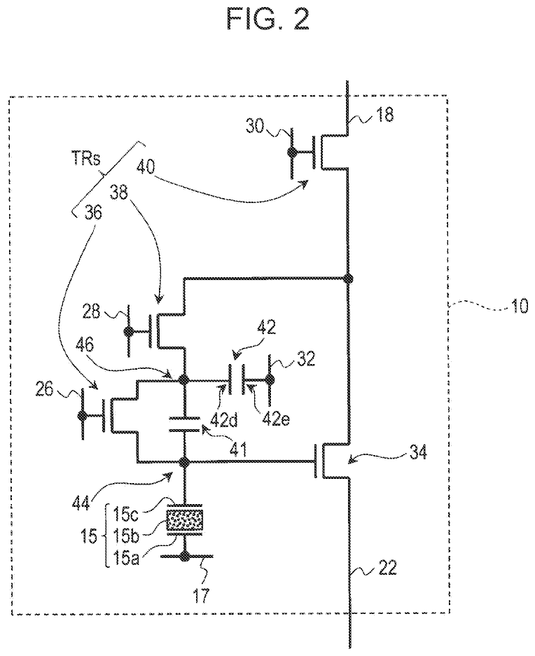

FIG. 2 is a diagram illustrating an exemplary circuit configuration of the pixel 10 according to Embodiment 1. The pixel 10 includes a photoelectric converter 15. The photoelectric converter 15 photoelectrically converts light incident on the photoelectric converter 15. In the example illustrated in FIG. 2, the photoelectric converter 15 includes a counter electrode 15a, a photoelectric conversion film 15b and a pixel electrode 15c. The photoelectric conversion film 15b is provided between the counter electrode 15a and the pixel electrode 15c. The photoelectric conversion film 15b is laid on the semiconductor substrate. The photoelectric conversion film 15b is made of an organic material or an inorganic material. The inorganic material is, for example, amorphous silicon. The pixel 10 is supplied with one or more voltages through the power-supply line 22. As described above, this “one or more voltages” may be either “two or more voltages” or “two different voltages”.

The counter electrode 15a is provided on the light-acceptance surface side of the photoelectric conversion film 15b. The counter electrode 15a is made of a transparent conductive material. An example of the transparent conductive material is indium tin oxide (ITO). The pixel electrode 15c is provided on the opposite side to the counter electrode 15a, with the photoelectric conversion film 15b interposed therebetween. The pixel electrode 15c collects electric charges generated by photoelectric conversion in the photoelectric conversion film 15b. The pixel electrode 15c is made of metal, such as aluminum or copper, polysilicon that is doped with impurities to be conductive, or the like.

As illustrated in FIG. 2, the counter electrode 15a is coupled to the accumulation control line 17. The pixel electrode 15c is coupled to a charge accumulation region 44. The potential of the counter electrode 15a is controlled through the accumulation control line 17 so that either holes or electrons of hole-electron pairs generated by photoelectric conversion can be collected by the pixel electrode 15c. In the case of using holes as signal charges, the potential of the counter electrode 15a needs to be higher than that of the pixel electrode 15c. In the following examples, the signal charges are holes. A voltage of about 10 V, for example, is applied to the counter electrode 15a through the accumulation control line 17. The signal charges thereby accumulate in the charge accumulation region 44. The signal charges may be electrons. The charge accumulation region 44 is referred to as a floating diffusion node in some cases.

The pixel 10 includes an amplification transistor 34, a reset transistor 36, a capacitive portion 41, and a capacitive element 42. In the illustrated configuration, the capacitive element 42 has a larger capacitance value than the capacitive portion 41. In the configuration illustrated in FIG. 2, one of the source and the drain of the reset transistor 36 and one electrode of the capacitive portion 41 are coupled to the charge accumulation region 44 and are electrically coupled to the pixel electrode 15c. The other of the source and the drain of the reset transistor 36 and the other electrode of the capacitive portion 41 are coupled to one electrode of the capacitive element 42. The capacitive portion 41 is coupled between the source and the drain of the reset transistor 36. Hereinafter, the node including the point of connection between the capacitive portion 41 and the capacitive element 42 is referred to as a reset drain node 46 in some cases.

Of the electrodes of the capacitive element 42, the electrode that is not coupled to the reset drain node 46 is coupled to the sensitivity adjustment line 32. The potential of the sensitivity adjustment line 32 is set to, for example, 0 V. The potential of the sensitivity adjustment line 32 does not need to be fixed when the imaging device 100 is in operation. For example, the sensitivity adjustment line 32 may be supplied with pulse voltage from the vertical scanning circuit 16, which is illustrated in FIG. 1.

As illustrated in FIG. 2, the gate of the amplification transistor 34 is coupled to the charge accumulation region 44. The gate of the amplification transistor 34 is electrically coupled to the pixel electrode 15c. One of the source and the drain of the amplification transistor 34 is coupled to the power-supply line 22. The “One of the source and the drain of the amplification transistor 34” is the drain when the amplification transistor 34 is an N-channel metal oxide semiconductor field effect transistor (MOSFET). The power-supply line 22 serves as a source-follower power supply. The other of the source and the drain of the amplification transistor 34 is coupled to the vertical signal line 18 through a later-described address transistor 40. The vertical signal line 18 is a signal line transmitting an electric signal outputted from the amplification transistor 34. The amplification transistor 34 and the load circuit 19, which is illustrated in FIG. 1, constitute a source follower circuit. The amplification transistor 34 amplifies a signal generated by the photoelectric converter 15.

As illustrated in FIG. 2, the pixel 10 includes the address transistor 40. The address transistor 40 is also referred to as a row selection transistor. As described above, one of the source and the drain of the amplification transistor 34 is coupled to the power-supply line 22. The other of the source and the drain of the amplification transistor 34 is coupled to the source or drain of the address transistor 40. The gate of the address transistor 40 is coupled to the address signal line 30.

As illustrated in FIG. 2, the pixel 10 includes the feedback transistor 38. As described above, the other of the source and the drain of the amplification transistor 34 is coupled to the address transistor 40. The other of the source and the drain of the amplification transistor 34 is coupled to one of the source and the drain of the feedback transistor 38. During noise cancel operation, a feedback path is established, starting from the charge accumulation region 44 and returning to the charge accumulation region 44 through the amplification transistor 34, the feedback transistor 38, and the capacitive portion 41 or reset transistor 36 in this order. The output from the amplification transistor 34 is subjected to negative feedback to enter the charge accumulation region 44 through the above feedback path.

Voltage depending on the amount of signal charges accumulated in the charge accumulation region 44 is applied to the gate of the amplification transistor 34. The amplification transistor 34 amplifies this voltage. In reading operation, the voltage amplified by the amplification transistor 34 is selectively read out as an electric signal by the address transistor 40.

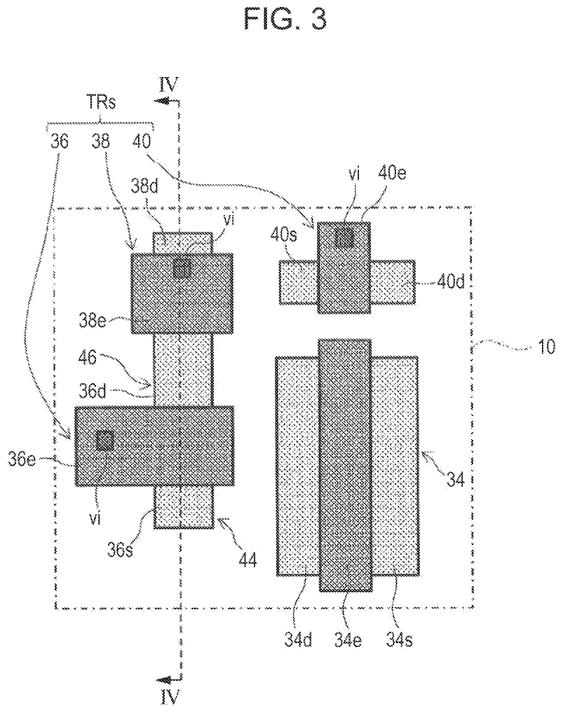

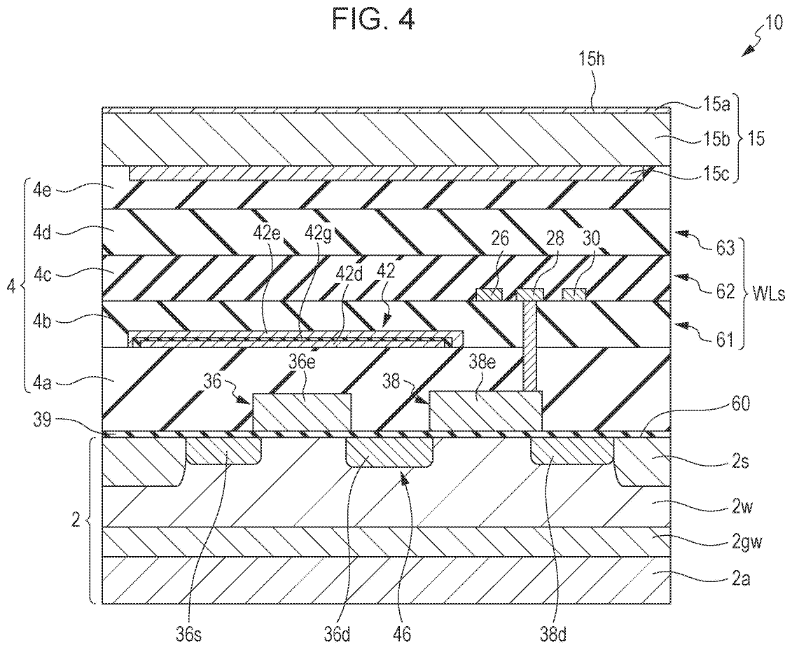

In Embodiment 1, the charge accumulation region 44 includes an impurity region provided in the semiconductor substrate 2. Specifically, this impurity region is the source or drain of the reset transistor 36. In the example illustrated in FIGS. 3 and 4 described later, this impurity region is a third diffusion layer 36s.

In Embodiment 1, as described above, the photoelectric converter 15 converts light into signal charges. The signal charges are accumulated in the charge accumulation region 44. The amplification transistor 34 generates an electric signal depending on the voltage of the charge accumulation region 44. The address transistor 40 determines the timing to output the electric signal from the amplification transistor 34. The reset transistor 36 resets the voltage of the charge accumulation region 44. The feedback transistor 38 is provided on the feedback path for negative feedback of the electric signal generated by the amplification transistor 34, to the charge accumulation region 44.

In each row, the reset signal line 26 couples the vertical scanning circuit 16 and the gate of the reset transistor 36. The address signal line 30 couples the vertical scanning circuit 16 and the gate of the address transistor 40. The feedback control line 28 couples the vertical scanning circuit 16 and the gate of the feedback transistor 38.

Each of the amplification transistor 34, reset transistor 36, feedback transistor 38, and address transistor 40 may be either an N-channel MOSFET or P-channel MOSFET. Not all these transistors need to be matched by N-or P-channel MOSFETs. In the following examples, the amplification transistor 34, reset transistor 36, feedback transistor 38, and address transistor 40 are N-channel MOSFETs.

### Plan View and Device Structure of Pixel

Next, the device structure of the pixel 10 will be described with reference to FIGS. 3 and 4.

FIG. 3 is a plan view schematically illustrating a layout example of some elements of the pixel according to Embodiment 1. FIG. 4 is a cross-sectional view schematically illustrating a cross section along a line IV-IV illustrated in FIG. 3.

The pixel 10 is structured using the semiconductor substrate 2. In the example described here, the semiconductor substrate 2 is a p-type silicon (Si) substrate.

In Embodiment 1, four transistors, including the amplification transistor 34, the reset transistor 36, the feedback transistor 38, and the address transistor 40, are arranged in the pixel 10. The amplification transistor 34, the reset transistor 36, the feedback transistor 38, and the address transistor 40 are provided in the semiconductor substrate 2. The elements of the pixel 10 are isolated from each other by an element isolation region 2s, which is provided in the semiconductor substrate 2. In this example, a pair of the reset transistor 36 and the feedback transistor 38 is isolated from a pair of the amplification transistor 34 and the address transistor 40 by the element isolation region 2s.

Between the reset transistor 36 and the feedback transistor 38, the reset drain node 46 is provided. The reset drain node 46 includes a fourth diffusion layer 36d, which is provided within the semiconductor substrate 2. In the illustrated example, the fourth diffusion layer 36d is one of the source and the drain of the feedback transistor 38. The fourth diffusion layer 36d is one of the source and the drain of the reset transistor 36. That is, the fourth diffusion layer 36d is shared by the feedback transistor 38 and the reset transistor 36.

The pixel 10 includes the photoelectric converter 15. The photoelectric converter 15 is provided above the semiconductor substrate 2. On the semiconductor substrate 2, an interlayer insulating layer 4 is provided. In the interlayer insulating layer 4, a first insulating layer 4a, a second insulating layer 4b, a third insulating layer 4c, a fourth insulating layer 4d, and a fifth insulating layer 4e are stacked on top of each other in this order. The first to fifth insulating layers 4a to 4e are made of, for example, silicon dioxide (SiO₂). Between the semiconductor substrate 2 and the photoelectric converter 15, plural wiring layers WLs are arranged. Specifically, the plural wiring layers WLs include a first wiring layer 61, a second wiring layer 62, and a third wiring layer 63. The second wiring layer 62 is positioned on the photoelectric converter 15 side of the first wiring layer 61. The third wiring layer 63 is positioned on the photoelectric converter 15 side of the second wiring layer 62. The first wiring layer 61 is provided within the second insulating layer 4b. The second wiring layer 62 is provided within the third insulating layer 4c. The third wiring layer 63 is provided within the fourth insulating layer 4d. The capacitive element 42 is included in the first wiring layer 61. The reset signal line 26, feedback control line 28, and address signal line 30 are included in the second wiring layer 62. The number of wiring layers and the number of insulating layers can be set to any number and are not limited to the example illustrated in the drawings.

On the fifth insulating layer 4e, the photoelectric conversion film 15b is laid. The photoelectric conversion film 15b includes a light-acceptance surface 15h. Light from an object enters the light-acceptance surface 15h. On the light-acceptance surface 15h, the counter electrode 15a is arranged. On the surface of the photoelectric conversion film 15b opposite to the light-acceptance surface 15h, the pixel electrode 15c is arranged. The pixel electrode 15c is electrically isolated from the pixel electrodes 15c of the other pixels 99.

In the configuration illustrated in FIG. 4, the semiconductor substrate 2 includes a support substrate 2a, a well 2w, and an impurity layer 2gw. The well 2w has a comparatively high acceptor concentration. Herein, the well 2w is a P-type region. The impurity layer 2gw is a region of the opposite conductive type to the well 2w. Herein, the impurity layer 2gw is an N-type region. The support substrate 2a and the well 2w are electrically coupled by a not-illustrated connection region provided in the impurity layer 2gw. The connection region is an impurity region of the same conductive type as the well 2w.

A first diffusion layer 34s, a second diffusion layer 34d, a third diffusion layer 36s, the fourth diffusion layer 36d, a fifth diffusion layer 38d, a sixth diffusion layer 40s, and a seventh diffusion layer 40d are regions of the opposite conductive type to the well 2w. Herein, the first diffusion layer 34s, the second diffusion layer 34d, the third diffusion layer 36s, the fourth diffusion layer 36d, the fifth diffusion layer 38d, the sixth diffusion layer 40s, and the seventh diffusion layer 40d are N-type regions.

On the semiconductor substrate 2, an insulating film 39 is provided. The insulating film 39 is, for example, a silicon dioxide film. On the insulating film 39, gates 34e, 36e, 38e, and 40e are provided. The gates 34e, 36e, 38e, and 40e are electrodes made of, for example, polysilicon.

As illustrated in FIG. 3, the amplification transistor 34 includes the first diffusion layer 34s, the second diffusion layer 34d, and the gate 34e. The amplification transistor 34 includes a part of the insulating film 39. One of the first diffusion layer 34s and the second diffusion layer 34d constitutes the source of the amplification transistor 34, and the other constitutes the drain of the amplification transistor 34. The aforementioned part of the insulating film 39 constitutes a gate insulating film of the amplification transistor 34. The gate 34e is provided on this gate insulating film.

The reset transistor 36 includes the third diffusion layer 36s, the fourth diffusion layer 36d, and the gate 36e. The reset transistor 36 includes a part of the insulating film 39. One of the third diffusion layer 36s and the fourth diffusion layer 36d constitutes the source of the reset transistor 36, and the other constitutes the drain of the reset transistor 36. The aforementioned part of the insulating film 39 constitutes a gate insulating film of the reset transistor 36. The gate 36e is provided on this gate insulating film.

The feedback transistor 38 includes the fourth diffusion layer 36d, the fifth diffusion layer 38d, and the gate 38e. The feedback transistor 38 includes a part of the insulating film 39. One of the fourth diffusion layer 36d and the fifth diffusion layer 38d constitutes the source of the feedback transistor 38, and the other constitutes the drain of the feedback transistor 38. The aforementioned part of the insulating film 39 constitutes a gate insulating film of the feedback transistor 38. The gate 38e is provided on this gate insulating film.

The address transistor 40 includes the sixth diffusion layer 40s, the seventh diffusion layer 40d, and the gate 40e. The address transistor 40 includes a part of the insulating film 39. One of the sixth diffusion layer 40s and the seventh diffusion layer 40d constitutes the source of the address transistor 40, and the other constitutes the drain of the address transistor 40. The aforementioned part of the insulating film 39 constitutes a gate insulating film of the address transistor 40. The gate 40e is provided on this gate insulating film.

As illustrated in FIG. 4, the capacitive element 42 includes a first electrode 42d, a second electrode 42e, and an insulating layer 42g. The insulating layer 42g is arranged between the first electrode 42d and the second electrode 42e. In the illustrated example, the first electrode 42d is positioned relatively low while the second electrode 42e is positioned relatively high. The insulating layer 42g has a film shape.

In Embodiment 1, the first electrode 42d and the second electrode 42e contain metal. The first electrode 42d and the second electrode 42e may contain a metal compound, polysilicon, or the like. The metal compound is, for example, a metal oxide. The insulating layer 42g contains, for example, a high-dielectric material, such as HfO₂, a nitride, or the like.

In Embodiment 1, the capacitive element 42 is a metal insulator metal (MIM) capacitive element. The MIM capacitive element is a capacitive element having an MIM structure. “M” in “MIM” indicates at least one of a metal or a metal compound. “I” in “MIM” indicates an insulator and is, for example, an oxide. That is, the MIM capacitive element is a concept including a metal oxide metal (MOM) capacitive element. The MOM capacitive element is a capacitive element having an MOM structure. Use of an MIM capacitive element allows the capacitive element 42 to have a high capacitance density. Use of an insulating material having a high dielectric as an insulator particularly easily allows the capacitive element 42 to have a high capacitance density.

The capacitive portion 41 can have the same characteristics as those described regarding the capacitive element 42. The capacitive portion 41 may be a capacitive element. The capacitive portion 41 may be parasitic capacitance between traces. The structure of the capacitive portion 41 and the structure of the capacitive element 42 may be the same or different.

In Embodiment 1, of the capacitive elements included in the pixel 10, the capacitive element 42 has the largest area in plan view. In Embodiment 1, a capacitive element is a concept not including parasitic capacitance. The parasitic capacitance is, for example, parasitic capacitance of a diffusion region, parasitic capacitance between traces, or the like.

The aforementioned expression “of the capacitive elements included in the pixel 10, the capacitive element 42 has the largest area in plan view” will be described. This expression intends to imply a mode in which the pixel 10 includes no capacitive element other than the capacitive element 42. The above expression also intends to imply a mode in which the pixel 10 includes plural capacitive elements and the capacitive element that has the largest area in plan view of the plural capacitive elements is the capacitive element 42.

The first electrode 42d is electrically coupled to the fourth diffusion layer 36d. The second electrode 42e is electrically coupled to the sensitivity adjustment line 32, which is illustrated in FIG. 2. The second electrode 42e has a predetermined voltage applied by a voltage source through the sensitivity adjustment line 32. Herein, the voltage source is the vertical scanning circuit 16. By controlling the potential of the second electrode 42e, the potential of the charge accumulation region 44 can be controlled. In other words, by adjusting the voltage to be supplied to the second electrode 42e through the sensitivity adjustment line 32, the sensitivity of the imaging device 100 can be adjusted. When a constant voltage is supplied to the second electrode 42e, the potential of the second electrode 42e can be maintained at a constant. This allows the second electrode 42e of the capacitive element 42 having a comparatively large capacitance value to serve as a shield electrode.

As described above, the plural pixels 99 constitute rows and columns. In the circuit configuration illustrated in FIG. 2, noise cancel operation is executed for a selected row. That is, noise cancel is typically performed by sequentially selecting the pixels 10 in the column direction.

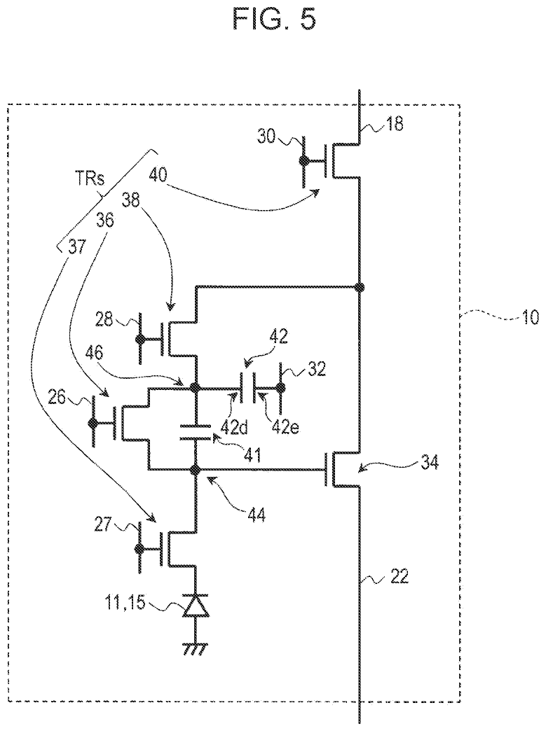

The photoelectric converter 15 may be a photodiode. The photodiode may be a pinned photodiode provided within the semiconductor substrate 2. A transfer transistor may be provided between the photoelectric converter 15 and the charge accumulation region 44. FIG. 5 is a diagram illustrating an exemplary circuit configuration of a pixel including a photodiode. In the example in FIG. 5, the photoelectric converter 15 is a photodiode 11. The charge accumulation region 44 is coupled to the photoelectric converter 15 through the transfer transistor 37. That is, the charge accumulation region 44 is coupled to the photoelectric converter 15. In FIG. 5, a transfer control line 27 is a control line transmitting to the transfer transistor 37, a control signal to control the transfer transistor 37.

The following description uses terms “plural pixels PXs”, “a first direction D1”, and “a second direction D2” in some cases. The plural pixels PXs are arrayed in the first direction D1. The plural pixels PXs are included in the plural pixels 99. The second direction D2 is perpendicular to the thickness direction of the semiconductor substrate 2 and the first direction D1. The first direction D1 can be one of the row and column directions. The second direction D2 can be the other of the row and column directions.

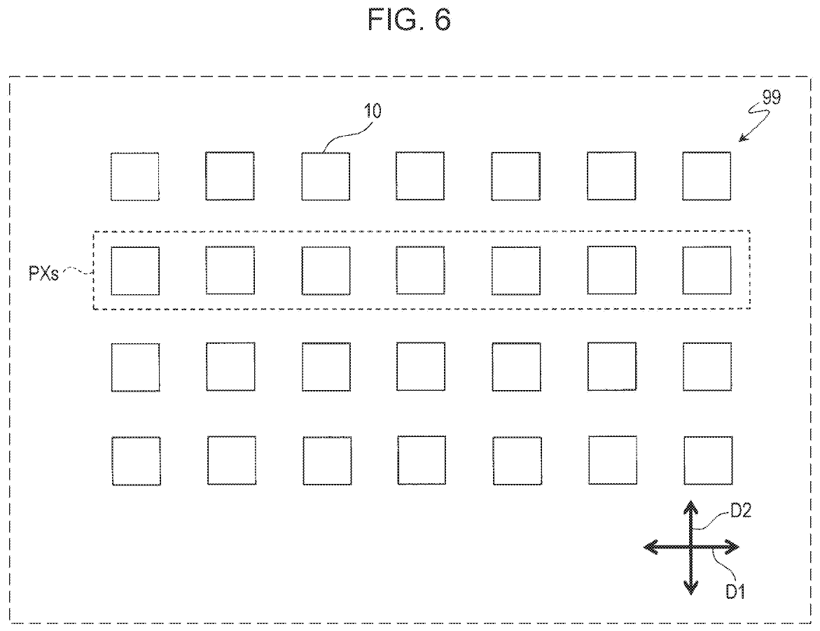

FIG. 6 is a schematic diagram for explaining the plural pixels PXs according to Embodiment 1. As illustrated in FIG. 6, the first direction D1 is the row direction in Embodiment 1. The second direction D2 is the column direction. The plural pixels PXs are arrayed in the row direction to constitute a row.

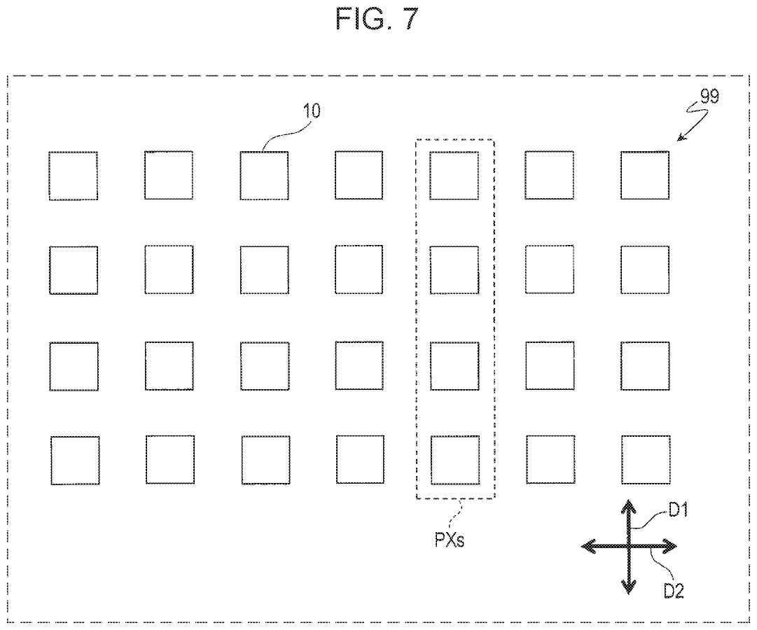

FIG. 7 is a schematic diagram for explaining the plural pixels PXs according to a modification. As illustrated in FIG. 7, the first direction D1 is the column direction in the modification. The second direction D2 is the row direction. The plural pixels PXs are arrayed in the column direction to constitute a column.

In Embodiment 1, the imaging device 100 includes the semiconductor substrate 2, the plural pixels PXs, and plural signal lines SLs. The plural pixels PXs are arrayed in the first direction D1 on the semiconductor substrate 2. The plural signal lines SLs are positioned above the semiconductor substrate 2. Each of the plural pixels PXs includes the photoelectric converter 15, the amplification transistor 34, plural transistors TRs, and the capacitive element 42. The photoelectric converter 15 converts light into signal charges. The gate 34e of the amplification transistor 34 receives the signal charges from the photoelectric converter 15. Each of the plural transistors TRs is electrically coupled to the corresponding signal line of the plural signal lines SLs.

As understood from FIGS. 1, 6, and 7 and other drawings, the imaging device 100 can include multiple combinations of the plural pixels PXs and the plural signal lines SLs. Specifically, the number of combinations included in the imaging device 100 may be one.

The aforementioned expression “Each of the plural pixels PXs includes the photoelectric converter 15, the amplification transistor 34, the plural transistors TRs, and the capacitive element 42” will be described. This expression does not intend to imply that all the pixels arrayed in the first direction D1 need to include these elements. It is therefore possible to employ a mode in which the pixels arrayed in the first direction D1 include a pixel different from the plural pixels PXs and the different pixel does not include any photoelectric converter, amplification transistor, plural transistors, or capacitive element.

The gate 34e of the amplification transistor 34 is coupled to the photoelectric converter 15. The expression “The gate 34e of the amplification transistor 34 is coupled to the photoelectric converter 15” will be described. This expression intends to imply a mode in which the gate 34e and the photoelectric converter 15 are electrically coupled without another transistor interposed therebetween. Furthermore, the above expression intends to imply a mode in which another transistor is interposed between the gate 34e and the photoelectric converter 15 and the gate 34e and the photoelectric converter 15 are electrically coupled to each other when the another transistor is on. For example, the expression implies a mode in which the transfer transistor 37 is interposed between the gate 34e and the photoelectric converter 15.

To each of the plural transistors TRs, a control signal is transmitted from the corresponding signal line of the plural signal lines SLs. Each of the plural transistors TRs is controlled with the control signal transmitted thereto. The “control signal” in “To each of the plural transistors TRs, a control signal is transmitted from the corresponding signal line of the plural signal lines SLs” will be described. As described above, a transistor is controlled with a control signal transmitted thereto. In this context, “a transistor is controlled” means that the gate-source voltage of the transistor is controlled in a typical example. By controlling the gate-source voltage, the transistor can be controlled on and off, and the operation region of the transistor can be controlled.

In Embodiment 1, the plural transistors TRs include the reset transistor 36. The plural transistors TRs include the feedback transistor 38. The plural transistors TRs include the address transistor 40. The plural transistors TRs may include the transfer transistor 37. On the other hand, the plural transistors TRs do not include the amplification transistor 34.

In Embodiment 1, the plural signal lines SLs extend in the first direction D1.

In Embodiment 1, the plural signal lines SLs include the reset signal line 26. The plural signal lines SLs include the feedback control line 28. The plural signal lines SLs include the address signal line 30. In a mode including the transfer transistor 37, the plural signal lines SLs can include the transfer control line 27.

In Embodiment 1, the plural signal lines SLs are M number of signal lines. M is a natural number greater than or equal to 1. M may be a natural number greater than or equal to 2, a natural number greater than or equal to 3, a natural number greater than or equal to 4, a natural number greater than or equal to 5, a natural number greater than or equal to 6, a natural number greater than or equal to 7, or a natural number greater than or equal to 8. M may be the total number of signal lines transmitting transistor control signals to the plural pixels PXs. In other words, the plural signal lines SLs may be all the signal lines constituting the signal lines transmitting transistor control signals.

The plural signal lines SLs may include all the signal lines that extend in the first direction D1 and are electrically coupled to the plural pixels PXs. In other words, the plural signal lines SLs may include all the signal lines that satisfy both first and second requirements. The first requirement is a requirement for a signal line to extend in the first direction D1. The second requirement is a requirement for a signal line to be electrically coupled to the plural pixels PXs.

In Embodiment 1, the imaging device 100 includes the vertical scanning circuit 16. The vertical scanning circuit 16 supplies control signals to the plural signal lines SLs.

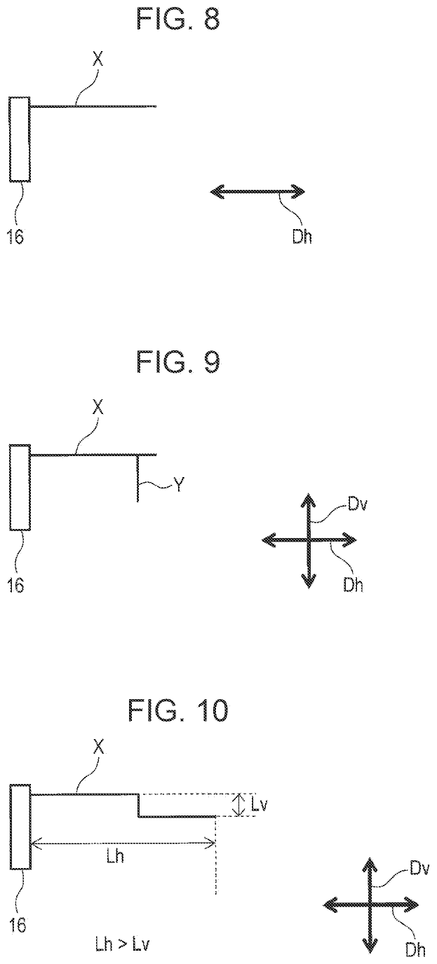

Hereinafter, the direction in which a signal line extends will be described. FIGS. 8 to 10 are plan views for explaining the direction in which a signal line X extends. In the following description, a horizontal direction Dh and a vertical direction Dv are perpendicular to each other.

In the example in FIG. 8, the entirety of the signal line X extends in the horizontal direction Dh. In the example in FIG. 8, the direction in which the signal line X extends is the horizontal direction Dh. Thus, the signal line X extends in the horizontal direction Dh.

In the example in FIG. 9, the entirety of the signal line X extends in the horizontal direction Dh. To the signal line X, a branch signal line Y is connected. The entirety of the branch signal line Y extends in the vertical direction Dv. In the example in FIG. 9, the direction in which the signal line X extends is based on the direction in which the signal line X extends but is not based on the direction in which the branch signal line Y extends. That is, the direction that the signal line X extends is the horizontal direction Dh. Thus, the signal line X extends in the horizontal direction Dh.

In the example in FIG. 10, the signal line X includes portions that extend in the horizontal direction Dh and have a length Lh in total and a portion that extends in the vertical direction Dv and has a length Lv. In the example in FIG. 10, the length Lh is longer than the length Lv. In the example in FIG. 10, the direction in which the signal line X extends is the direction concerning the longer of the lengths Lh and Lv. Since Lh>Lv, the direction in which the signal line X extends is the horizontal direction Dh. That is, the signal line X extends in the horizontal direction Dh.

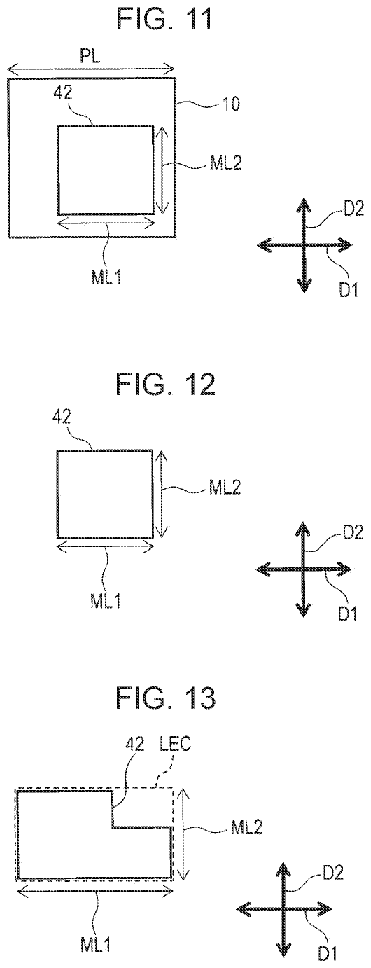

FIG. 11 is a plan view for explaining the dimensions of the capacitive element 42. In Embodiment 1, a maximum length ML1 of the capacitive element 42 in the first direction D1 is greater than one third of a length PL of the pixel 10 in the first direction D1 in plan view. The maximum length ML1 of the capacitive element 42 in the first direction D1 may be greater than half of the length PL of the pixel 10 in the first direction D1. The boundary of each pixel 10 may be a virtual median line defined based on the region where the constituent elements of each pixel 10 are arranged. For example, the boundary of each pixel 10 may be the median line between the pixel electrodes 15c of the pixel 10 and a pixel 10 adjacent thereto.

In Embodiment 1, the maximum length ML1 of the capacitive element 42 in the first direction D1 is greater than the maximum length ML2 of the capacitive element 42 in the second direction D2 in plan view.

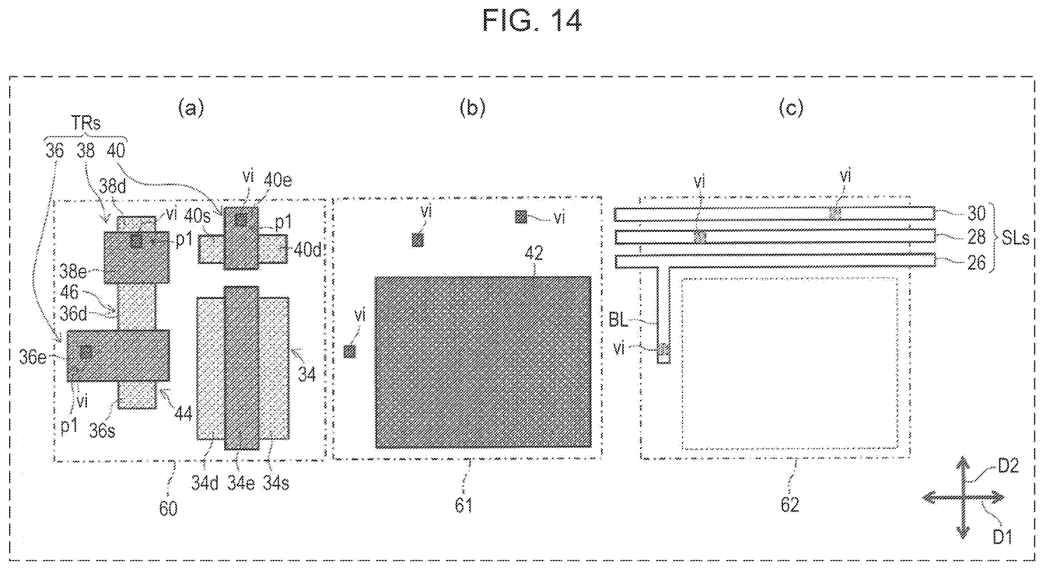

The maximum lengths ML1 and ML2 will be described with reference to FIGS. 12 and 13. FIGS. 12 and 13 are plan views for explaining the maximum lengths ML1 and ML2 of the capacitive element 42.

In the example in FIG. 12, the capacitive element 42 is a rectangle in plan view. Herein, a rectangle is a concept including a square. In the example in FIG. 12, the length of one of the two sides of this rectangle is the maximum length ML1 while the length of the other is the maximum length ML2.

In the example in FIG. 13, the capacitive element 42 has a shape obtained by removing a part from a rectangle in plan view. A rectangle which is the minimum rectangle that can accommodate the partially-removed rectangle and has a side extending in the first direction D1 and another side extending in the second direction D2 is defined as a rectangle LEC. Herein, a rectangle is a concept including a square. In the example in FIG. 13, one of the two sides of the rectangle LEC has the maximum length ML1, and the other has the maximum length ML2. When the capacitive element 42 has another shape in plan view, the maximum lengths ML1 and ML2 can be defined in a similar manner.

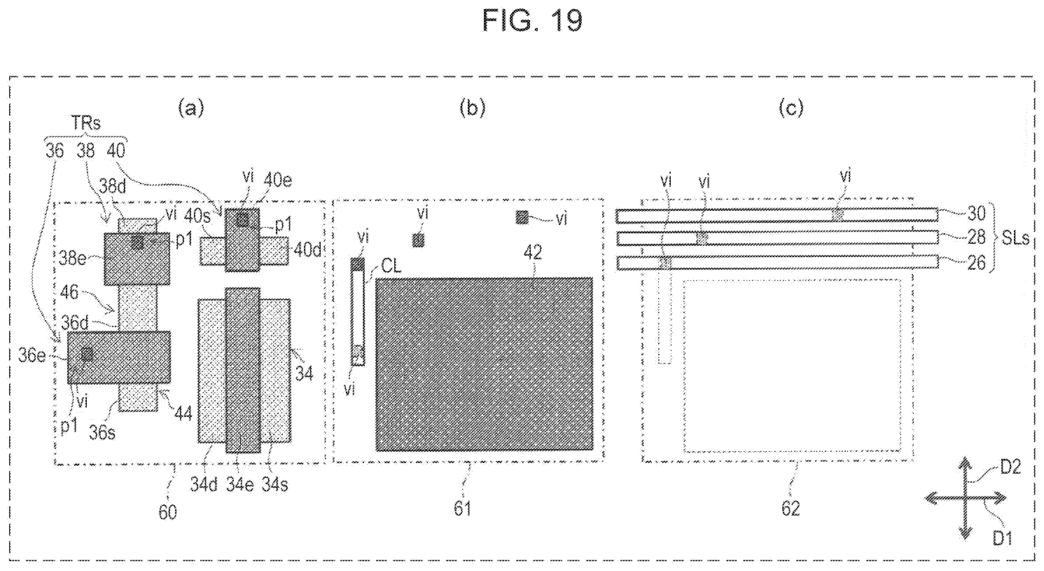

FIG. 14 is a plan view schematically illustrating a layout example of some traces and some elements in a pixel according to Embodiment 1. In FIG. 14, Part (a), Part (b), and Part (c) are sequentially arranged, starting from the left. Part (a) illustrates the arrangement of the transistors in a surface 60 of the semiconductor substrate 2. Part (b) illustrates the arrangement of the capacitive element 42 and traces in the first wiring layer 61. Part (c) illustrates the arrangement of traces in the second wiring layer 62. In term of these points, the same applies to FIGS. 19 to 24 described later.

As understood from FIG. 14, in Embodiment 1, the capacitive element 42 does not overlap the entire width of any one of the plural signal lines SLs in plan view. According to this configuration, it is possible to reduce the parasitic capacitance between the plural signal lines SLs and the capacitive element 42 and minimize delay of signals flowing through the plural signal lines SLs. This configuration is therefore suitable for providing the imaging device 100 capable of implementing high-speed imaging.

Herein, the expression “the capacitive element 42 does not overlap the entire line width of any one of the plural signal lines SLs in plan view” will be described herein. This expression intends to imply a mode in which there is no overlap between the plural signal lines SLs and the capacitive element 42 in plan view. This expression intends to imply a mode in which, in plan view, there is an overlap between the plural signal lines SLs and the capacitive element 42 but the width of the overlap between the signal line including the overlap and the capacitive element 42 is less than the line width of the signal line.

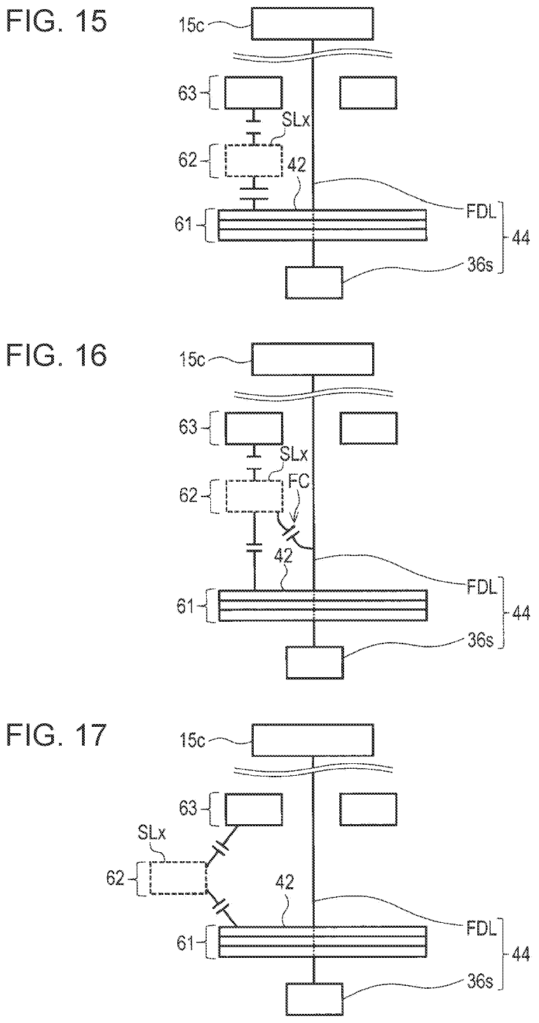

The advantages in the aforementioned configuration will be further described with reference to FIGS. 15 to 17. FIGS. 15 to 17 illustrate only a signal line SLx of the plural signal lines SLs. The signal line SLx can correspond to the reset signal line 26. The signal line SLx can correspond to the feedback control line 28. The signal line SLx can correspond to the address signal line 30. The signal line SLx can correspond to the transfer control line 27.

FIG. 15 is a cross-sectional view schematically illustrating a cross-section of an imaging device according to a first reference example. Specifically, the cross-section is parallel to the thickness direction of the semiconductor substrate 2. In the first reference example, the capacitive element 42 overlaps the entire line width of the signal line SLx in plan view. In this case, it is difficult to reduce the parasitic capacitance between the signal line SLx and the capacitive element 42 and minimize delay of signals flowing through the signal line SLx. This configuration has a disadvantage in terms of providing an imaging device capable of implementing high-speed imaging.

FIG. 16 is a cross-sectional view schematically illustrating a cross-section of an imaging device according to a second reference example. Specifically, the cross-section is parallel to the thickness direction of the semiconductor substrate 2. In the second reference example, the capacitive element 42 overlaps the entire line width of the signal line SLx in plan view. In the second reference example, however, the distance between the signal line SLx and the capacitive element 42 in the thickness direction of the semiconductor substrate 2 is greater than that in the first reference example. Such a configuration can reduce the parasitic capacitance between the signal line SLx and the capacitive element 42. However, when the aforementioned distance is increased, an electric path FDL electrically coupling the pixel electrode 15c and the third diffusion layer 36s tends to increase. Since the charge accumulation region 44 includes the third diffusion layer 36s and the electric path FDL, the capacitance of the charge accumulation region 44 increases with the length of the electric path FDL. This means that the sensitivity of the imaging device 100 is thereby deteriorated. It also means that fringe capacitance FC between the signal line SLx and the electric path FDL tends to increase. The electric path FDL can be composed of a via, a trace, and the like.

FIG. 17 is a cross-sectional view schematically illustrating a cross-section of the imaging device 100 according to Embodiment 1. Specifically, the cross-section is parallel to the thickness direction of the semiconductor substrate 2. In Embodiment 1, the capacitive element 42 does not overlap the entire line width of the signal line SLx in plan view. According to this configuration, it is possible to reduce the parasitic capacitance between the signal line SLx and the capacitive element 42 and minimize delay of signals flowing through the signal line SLx. This configuration is therefore suitable for providing an imaging device capable of implementing high-speed imaging. As understood from the comparison with the second reference example illustrated in FIG. 16, according to the configuration in FIG. 17, the parasitic capacitance between the signal line SLx and the capacitive element 42 can be reduced without the electric path FDL increasing in length. This configuration is therefore suitable for ensuring the high sensitivity of the imaging device 100 and reducing the fringe capacitance FC. The configuration in which “the capacitive element 42 does not overlap the entire line width of any one of the plural signals SLs in plan view” is therefore even more suitable.

As understood from the description using FIGS. 15 to 17, when the distance between the pixel electrode 15c and the semiconductor substrate 2 is properly reduced, the electric path FDL can be properly shortened. It is therefore possible to avoid the situation where the imaging device 100 fails to have high sensitivity due to the increased capacitance of the charge accumulation region 44. The distance between the pixel electrode 15c and the semiconductor substrate 2 is, for example, greater than or equal to 1 μm and less than or equal to 5 μm. Specifically, the distance may be greater than or equal to 2 μm and less than or equal to 4 μm.

Specifically, as understood from FIG. 14, in Embodiment 1, the capacitive element 42 does not overlap half or more than half of the line width of any one of the plural signal lines SLs in plan view. This configuration is suitable for providing the imaging device 100 capable of implementing high-speed imaging.

More specifically, in Embodiment 1, the capacitive element 42 does not overlap any one of the plural signal lines SLs in plan view. In other words, none of the plural signal lines SLs has an overlap with the capacitive element 42 in plan view. Each of the plural signal lines SLs may be spaced from the capacitive element 42 in plan view. This configuration is suitable for providing the imaging device 100 capable of implementing high-speed imaging.

In Embodiment 1, voltages different from the voltages applied to the second electrode 42e of the capacitive element 42 are applied to the plural signal lines SLs. In such a situation where different voltages are applied, the parasitic capacitance tends to have a negative effect on signals flowing through the plural signal lines SLs. However, in Embodiment 1, the parasitic capacitance between the plural signal lines SLs and the capacitive element 42 can be reduced based on the layout of the plural signal lines SLs and the capacitive element 42 as described above. The aforementioned negative effect can therefore be minimized.

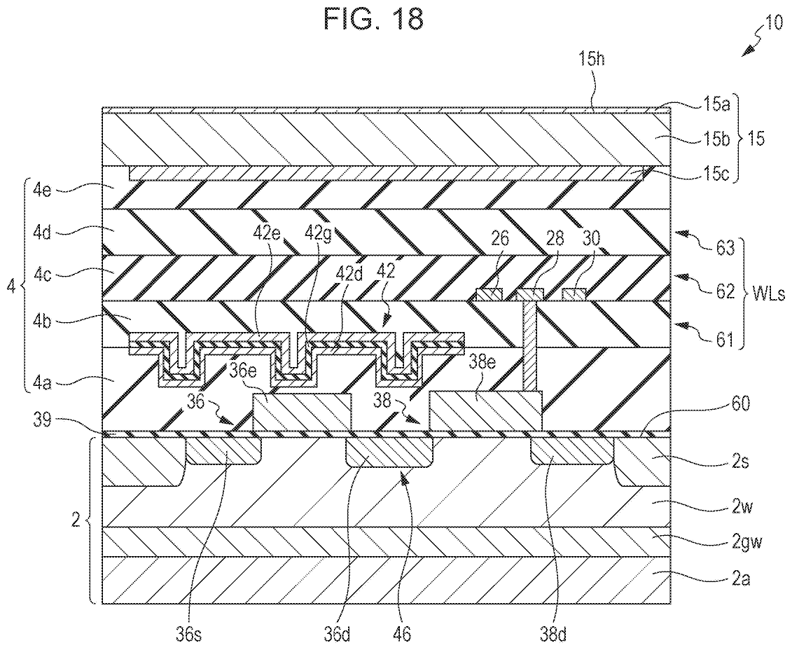

The capacitive element 42 may have a trench structure. FIG. 18 is a cross-sectional view illustrating the capacitive element 42 having a trench structure. By having a trench structure, the capacitive element 42 easily ensures a high capacitance value. Herein, the trench structure refers to a structure including bending portions. Specifically, in the capacitive element 42 having a trench structure, the first electrode 42d, the second electrode 42e, and the insulating layer 42g include bending portions.

When the capacitive element 42 or the like occupies a large area, conductive foreign substances generated during a semiconductor manufacturing process are more likely to form a leak path between the capacitive element 42 and the plural signal lines SLs. In Embodiment 1, the capacitive element 42 does not overlap the entire line width of any one of the plural signal lines SLs in plan view as described above. According to this configuration, it is less likely to cause a situation in which remaining conductive foreign substances cause a leak and reduce the yield.

In Embodiment 1, the imaging device 100 includes the plural wiring layers WLs. The plural wiring layers WLs include the first wiring layer 61 and the second wiring layer 62. In the plural wiring layers WLs, the first wiring layer 61 and the second wiring layer 62 are adjacent to each other. The capacitive element 42 is structured using the first wiring layer 61. The plural signal lines SLs are included in the second wiring layer 62. In a specific example, as illustrated in FIG. 4, the first electrode 42d and the second electrode 42e both belong to the first wiring layer 61. In another specific example, the plural wiring layers WLs include a 0th wiring layer that is adjacent to the first wiring layer 61 and is positioned on the opposite side of the first wiring layer 61 to the second wiring layer 62. That is, the 0th wiring layer, the first wiring layer 61, and the second wiring layer 62 are arranged in this order. The first electrode 42d belongs to the 0th wiring layer, and the second electrode 42e belongs to the first wiring layer 61.

In Embodiment 1, the plural transistors TRs include a second transistor. One of the source and the drain of the second transistor is coupled to the photoelectric converter 15. The plural signal lines SLs include a second signal line. The second signal line is electrically coupled to the gate of the second transistor. In Embodiment 1, the second signal line extends in the first direction D1.

The combination of the second transistor and the second signal line can be the combination of the reset transistor 36 and the reset signal line 26. The combination of the second transistor and the second signal line can be the combination of the transfer transistor 37 and the transfer control line 27.

The aforementioned expression “One of the source and the drain of the second transistor is coupled to the photoelectric converter 15” will be described. This expression intends to imply a mode in which one of the source and the drain of the second transistor and the photoelectric converter 15 are electrically coupled without another transistor interposed therebetween. This expression also intends to imply a mode in which another transistor is interposed between one of the source and the drain of the second transistor and the photoelectric converter 15 and the one of the source and the drain of the second transistor and the photoelectric converter 15 are electrically coupled when the another transistor is on. The combination of the second transistor and the second signal line can therefore be the combination of the feedback transistor 38 and the feedback control line 28. The combination of the second transistor and the second signal line can be the combination of the address transistor 40 and the address signal line 30.

In Embodiment 1, the plural transistors TRs include a third transistor. The plural signal lines SLs include a third signal line. The gate of the third transistor is electrically coupled to the third signal line. Specifically, the gate of each of the plural transistors TRs can be electrically coupled to the corresponding signal line of the plural signal lines SLs. In Embodiment 1, the third signal line extends in the first direction D1.

The combination of the third transistor and the third signal line can be the combination of the reset transistor 36 and the reset signal line 26. The combination of the third transistor and the third signal line can be the combination of the feedback transistor 38 and the feedback control line 28. The combination of the third transistor and the third signal line can be the combination of the address transistor 40 and the address signal line 30. The combination of the third transistor and the third signal line can be the combination of the transfer transistor 37 and the transfer control line 27.

Back to FIG. 14, in Embodiment 1, each of the gates of the plural transistors TRs includes a first portion p1 that does not overlap the capacitive element 42 in plan view. Each of the first portions p1 of the plural transistors TRs is electrically coupled to the corresponding signal line of the plural signal lines SLs. In this configuration, the capacitive element 42 does not overlap the first portion p1 in plan view, so that the capacitive element 42 is less likely to interfere with arrangement of an electric path coupling the signal line and the first portion p1.

Each of the plural transistors TRs may overlap the capacitive element 42. For example, in FIG. 14, part of the reset transistor 36 and part of the feedback transistor 38 overlap the capacitive element 42. In other words, the gate 36e, the third diffusion layer 36s, and the fourth diffusion layer 36d of the reset transistor 36 overlap the capacitive element 42. The gate 38e and the fourth diffusion layer 36d of the feedback transistor 38 overlap the capacitive element 42.

In Embodiment 1, each of the first portions p1 of the plural transistors TRs has a portion overlapping the corresponding signal of the plural signal lines SLs in plan view. According to this configuration, it is possible to employ a layout in which an electric path coupling the signal line and the first portion p1 is provided for the overlapping portion in plan view.

In Embodiment 1, the imaging device 100 includes plural vias vi. Each of the first portions p1 of the plural transistors TRs is electrically coupled to the corresponding signal line of the plural signal lines SLs through the corresponding via of the plural vias vi.

In Embodiment 1, in each of the plural transistors TRs, voltage from the corresponding signal line of the plural signal lines SLs is applied to the first portion p1, that is, the gate electrode of the corresponding transistor TRs.

In Embodiment 1, the imaging device 100 includes a branch signal line BL. The plural signal lines SLs include the first signal line. The branch signal line BL extends from the first signal line. The direction in which the branch signal line BL extends is different from the direction in which the first signal line extends in plan view. The plural transistors TRs include the first transistor. The first signal line, the branch signal line BL, and the gate of the first transistor are electrically coupled in this order. In Embodiment 1, the first signal line extends in the first direction D1.

In Embodiment 1, the branch signal line BL does not overlap the capacitive element 42 in plan view. In this configuration, since the branch signal line BL does not overlap the capacitive element 42 in plan view, the capacitive element 42 is less likely to interfere with arrangement of an electric path coupling the branch signal line BL and the gate of the first transistor.

In Embodiment 1, the branch signal line BL has a portion overlapping the gate of the first transistor in plan view. According to this configuration, it is possible to employ a layout in which the electric path coupling the branch signal line BL and the gate of the first transistor is provided for the overlapping portion in plan view.

In Embodiment 1, the first signal line is electrically coupled to the gate of the first transistor with the branch signal line BL and the via vi interposed in this order.

In Embodiment 1, the branch signal line BL and the first signal line extend in different directions and are electrically coupled through the via vi. According to this configuration, it is possible to minimize the parasitic capacitance between the capacitive element 42 and the path through which control signals flow and improve the flexibility of the wiring layout to electrically couple the gate of the first transistor and the first signal line.

In Embodiment 1, the plural vias vi extend in the thickness direction of the semiconductor substrate 2. The first signal line extends in the first direction D1. The branch signal line BL extends in the second direction D2.

In the example of FIG. 14, the combination of the first transistor and the first signal line is the combination of the reset transistor 36 and the reset signal line 26. The combination of the first transistor and the first signal line may be the combination of the feedback transistor 38 and the feedback control line 28. The combination of the first transistor and the first signal line may be the combination of the address transistor 40 and the address signal line 30. The combination of the first transistor and the first signal line may be the combination of the transfer transistor 37 and the transfer control line 27. In terms of these points, the same applies to the later-described embodiments.

The first transistor, the second transistor, and the third transistor may be the same transistor. Two transistors selected from a group consisting of the first transistor, the second transistor, and the third transistors may be the same single transistor while the other is a different transistor. The first transistor, the second transistor, and the third transistor may be three different transistors.

The first signal line, the second signal line, and the third signal line may be the same signal line. Two signal lines selected from a group consisting of the first signal line, the second signal line, and the third signal line may be the same signal line while the other is a different signal line. The first signal line, the second signal line, and the third signal line may be three different signal lines.

Hereinafter, some other embodiments will be described. The elements of later-described embodiments that are the same as those of the aforementioned embodiment are given the same reference numerals, and the description thereof is omitted in some cases. In addition, the description of the operation and effects of the later-described embodiments that are the same as those of the aforementioned embodiment is omitted in some cases. The description concerning each embodiment can be applied to the other embodiments without any technical contradiction. The embodiments may be combined without any technical contradiction.

### Embodiment 2

FIG. 19 is a plan view schematically illustrating a layout example of some traces and some elements in a pixel according to Embodiment 2.

In Embodiment 2, an imaging device does not include the branch signal line BL unlike Embodiment 1. The imaging device includes a connecting line CL instead. In Embodiment 2, the connecting line CL is provided at a position different from the capacitive element 42 in the first wiring layer 61. Specifically, the connecting line CL is physically and electrically isolated from the capacitive element 42.

The direction in which the connecting line CL extends is different from the direction in which the first signal line extends. The first signal line is electrically coupled to the gate of the first transistor with a certain via vi, the connecting line CL, and another via vi interposed in this order. Typically, these two vias vi extend in the thickness direction of the semiconductor substrate 2. In Embodiment 2, the first signal line extends in the first direction D1. The connecting line CL extends in the second direction D2.

In Embodiment 2, the connecting line CL and the first signal line extend in different directions and are electrically coupled through the via vi. According to this configuration, it is possible to minimize the parasitic capacitance between the capacitive element 42 and the path through which control signals flow and improve the flexibility of the wiring layout to electrically couple the gate of the first transistor and the first signal line.

In the example in FIG. 19, the combination of the first transistor and the first signal line is the combination of the reset transistor 36 and the reset signal line 26. The reset signal line 26 is electrically coupled to the gate 36e of the reset transistor 36 with a certain via vi, the connecting line CL, and another via vi interposed in this order.

The combination of the first transistor and the first signal line may be the combination of the feedback transistor 38 and the feedback control line 28. In this case, the feedback control line 28 can be electrically coupled to the gate 38e of the feedback transistor 38 with a certain via vi, the connecting line CL, and another via vi interposed in this order.

The combination of the first transistor and the first signal line may be the combination of the address transistor 40 and the address signal line 30. In this case, the address signal line 30 can be electrically coupled to the gate 40e of the address transistor 40 with a certain via vi, the connecting line CL, and another via vi interposed in this order.

The combination of the first transistor and the first signal line may be the combination of the transfer transistor 37 and the transfer control line 27. In this case, the transfer control line 27 can be electrically coupled to the gate of the transfer transistor 37 with a certain via vi, the connecting line CL, and another via vi interposed in this order.

### Embodiment 3

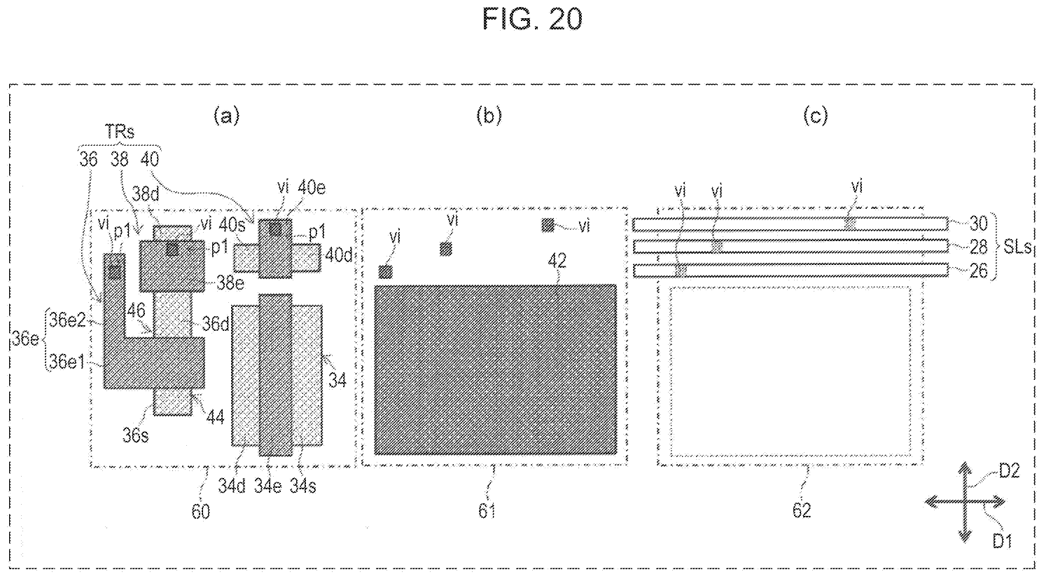

FIG. 20 is a plan view schematically illustrating a layout example of some traces and some elements in a pixel according to Embodiment 3.

In Embodiment 3, the imaging device does not include the branch signal line BL unlike Embodiment 1. The gate shape of the first transistor of Embodiment 3 is different from the gate shape of the first transistor of Embodiment 1 in plan view.

Specifically, the gate of the first transistor of Embodiment 3 includes a base portion and an extension portion. The base portion has the same shape as the gate of the first transistor of Embodiment 1. The extension portion extends in a direction different from the direction in which the first signal line extends. Herein, the direction in which the extension portion extends refers to, for example, the longitudinal direction of the extension portion in plan view. The first signal line is electrically coupled to the extension portion through vias vi. In Embodiment 3, the first signal line extends in the first direction D1. The extension portion extends from the base portion in the second direction D2. In this example, the dimension of the extension portion in the first direction D1 is smaller than that of the base portion. The dimension of the extension portion in the second direction D2 is greater than that of the base portion.

In Embodiment 3, as described above, the extension portion and the first signal line extend in different directions and are electrically coupled through the vias vi. According to this configuration, it is possible to minimize the parasitic capacitance between the capacitive element 42 and the path through which control signals flow and improve the flexibility of the wiring layout to electrically couple the gate of the first transistor and the first signal line.

In the example of FIG. 20, the combination of the first transistor and the first signal line is the combination of the reset transistor 36 and the reset signal line 26. The gate 36e of the reset transistor 36 includes a base portion 36e1 and an extension portion 36e2.

The combination of the first transistor and the first signal line may be the combination of the feedback transistor 38 and the feedback control line 28. In this case, the gate 38e of the feedback transistor 38 can include the base portion and the extension portion.

The combination of the first transistor and the first signal line may be the combination of the address transistor 40 and the address signal line 30. In this case, the gate 40e of the address transistor 40 can include the base portion and the extension portion.

The combination of the first transistor and the first signal line may be the combination of the transfer transistor 37 and the transfer control line 27. In this case, the gate of the transfer transistor 37 can include the base portion and the extension portion.

### Embodiment 4

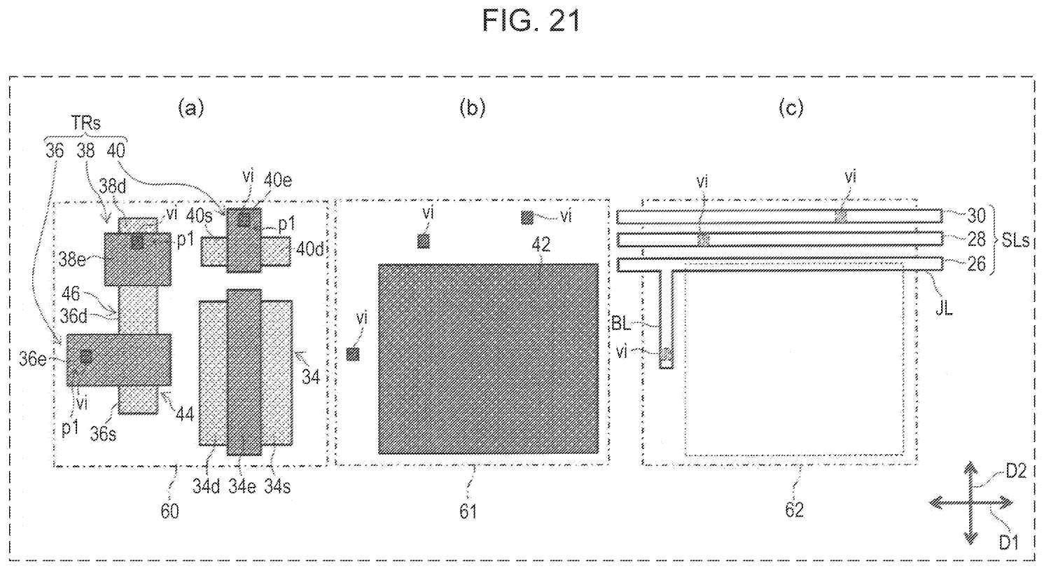

FIG. 21 is a plan view schematically illustrating a layout example of some traces and some elements in a pixel according to Embodiment 4.

In Embodiment 4, the capacitive element 42 overlaps half of the line width of a signal line JL of the plural signal lines SLs in plan view unlike Embodiment 1. Even in this configuration, it is possible to reduce the parasitic capacitance between the signal line JL and the capacitive element 42 compared to the case where the capacitive element 42 overlaps the entire line width of the signal line JL in plan view.

More generally, the capacitive element 42 may overlap J % of the line width of the signal line JL where J is greater than 0 and less than or equal to 50. In Embodiment 4, J is 50.

In the example of FIG. 21 the signal line JL is the reset signal line 26. The signal line JL may be the feedback control line 28, the address signal line 30, or the transfer control line 27.

In the example of FIG. 21, the number of signal lines whose J % (0<J<=50) of the line width overlaps the capacitive element 42 in plan view is one. This number may be greater than one.

### Embodiment 5

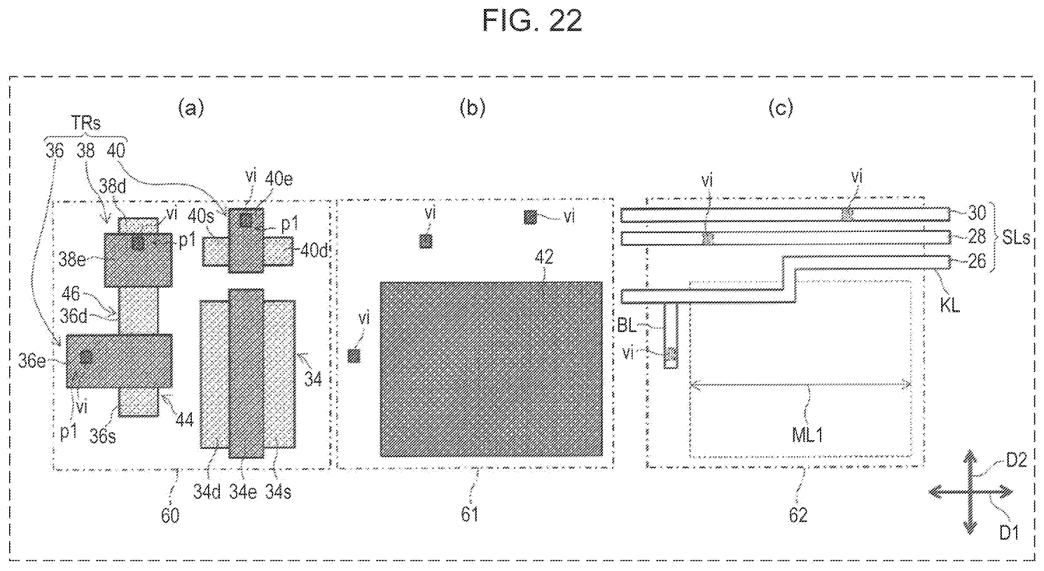

FIG. 22 is a plan view schematically illustrating a layout example of some traces and some elements in a pixel according to Embodiment 5.

In Embodiment 5, a signal line KL of the plural signal lines SLs has a bent shape in plan view unlike Embodiment 1. The signal line KL overlaps half of the maximum length ML1 of the capacitive element 42 in the first direction D1 in plan view. Even in this configuration, it is possible to reduce the parasitic capacitance between the signal line KL and the capacitive element 42 compared to the case where the signal line KL overlaps the maximum length ML1 of the capacitive element 42 in plan view.

More generally, the signal line KL may overlap K % of the maximum length ML1 of the capacitive element 42 in plan view where K is greater than 0 and less than or equal to 50. In Embodiment 5, K is 50.

In the example of FIG. 22, the signal line KL is the reset signal line 26. The signal line KL may be the feedback control line 28, the address signal line 30, or the transfer control line 27.

In the example of FIG. 22, the number of signal lines overlapping K % (0<K<=50) of the maximum length ML1 of the capacitive element 42 in plan view is one. This number may be greater than one.

In the example of FIG. 22, the reset signal line 26 has a bent shape in plan view. The feedback control line 28 may have a bent shape in plan view. The address signal line 30 may have a bent shape in plan view. The transfer control line 27 may have a bent shape in plan view.

Embodiment 5 described with reference to FIG. 22 and the previously described embodiments lead to the following technique;
None of the plural signal lines SLs overlaps half or more than half of the maximum length ML1 of the capacitive element 42 in the first direction D1 in plan view.

According to this configuration, it is possible to reduce the parasitic capacitance between the capacitive element 42 and the plural signal lines SLs and minimize delay of signals flowing through the plural signal lines SLs. This configuration is therefore suitable for providing the imaging device 100 capable of implementing high-speed imaging.

### Other Embodiments

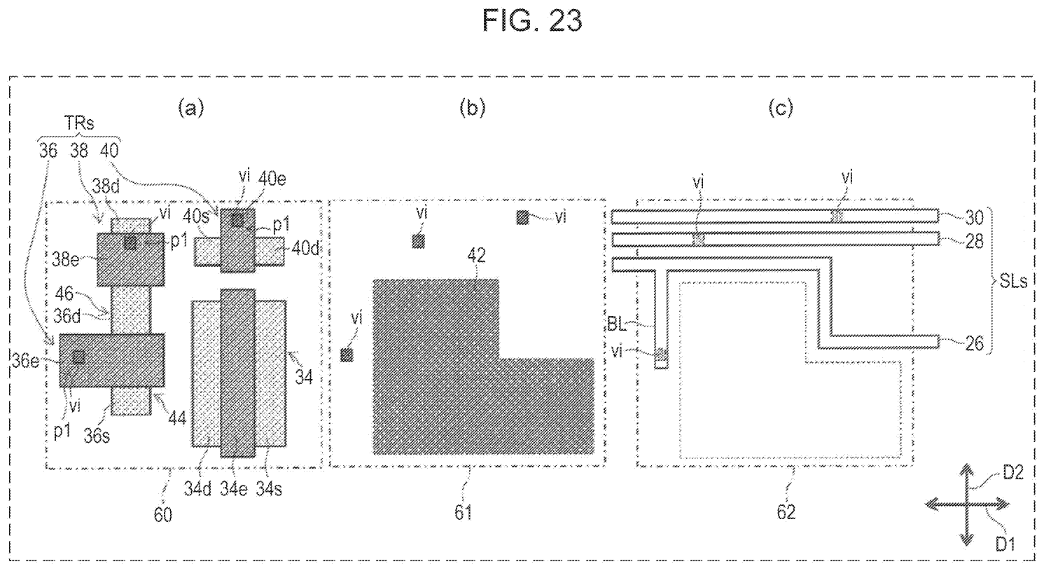

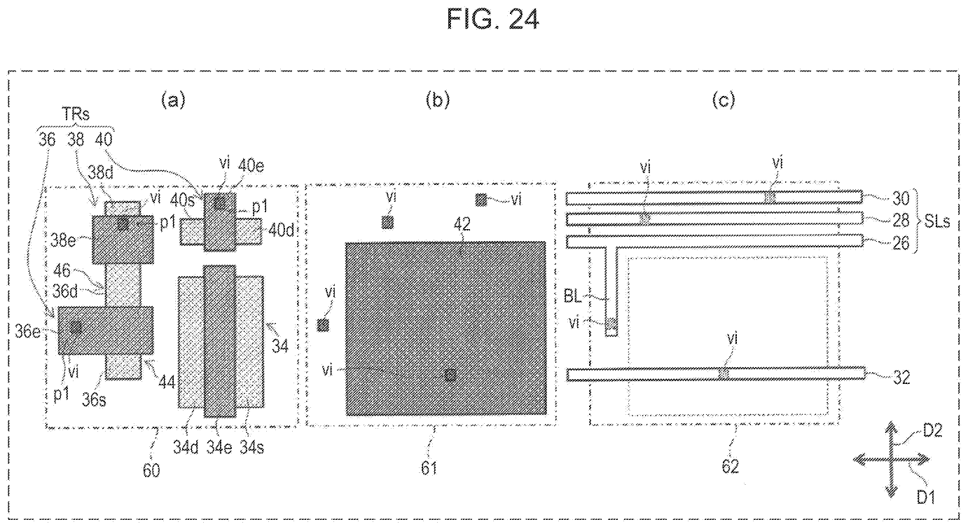

Hereinafter, other embodiments will be described. FIGS. 23 and 24 are plan views schematically illustrating a layout example of some traces and some elements in a pixel according to other embodiments.

For example, as illustrated in FIG. 23, Embodiment 1 may be combined with the characteristic that at least one of the plural signal lines SLs has a bent shape not extending linearly.

For example, the capacitive element 42 does not need to be rectangular, as illustrated in FIG. 23.

As described above, the plural signal lines SLs individually transmit transistor control signals to the plural transistors TRs. In an example, trances other than signal lines transmitting the transistor control signals are arranged so as to overlap the capacitive element 42 in plan view. In the example in FIG. 24, the sensitivity adjustment line 32 overlaps the capacitive element 42 in plan view. The sensitivity adjustment line 32 is coupled to the first electrode 42d of the capacitive element 42. That is, the sensitivity adjustment line 32 has the same potential as the first electrode 42d, thus not causing any parasitic capacitance problem. All the signal lines do not need to have an overlap with the capacitive element 42 in plan view.

In the aforementioned embodiments, the plural signal lines SLs are individually coupled to the gates of the plural transistors TRs. The plural signal lines SLs may include a wiring line coupled to the source or drain of a transistor. In an example, a transistor is controlled by a signal flowing through a wiring line coupled to the source or drain of the transistor. In a typical example, this signal controls the gate-source voltage of the transistor. All the plural signal lines SLs may be coupled to the source or drain of the corresponding transistors.

It is possible to employ a mode in which plural photoelectric converters are provided within one pixel. It is possible to employ a mode in which the photoelectric converters are photodiodes. Furthermore, it is possible to employ a mode in which a photoelectric converter including a photoelectric conversion film arranged between a pair of electrodes and a photoelectric converter composed of a photodiode are provided within a pixel.

The technique according to the present disclosure can reduce parasitic capacitance of signal lines and implement high-speed imaging. The technique according to present disclosure is useful for digital cameras and the like.

What is claimed is:

1. An imaging device comprising:
a semiconductor substrate;
a plurality of pixels arrayed in a first direction on the semiconductor substrate; and
a first signal line positioned above the semiconductor substrate, wherein
each of the plurality of pixels includes:
a photoelectric converter that converts light into signal charges;
a transistor that includes a gate electrically coupled to the first signal line; and
a capacitive element,
in a first pixel of the plurality of pixels,
at least a part of the transistor overlaps the capacitive element in plan view, and
the capacitive element does not overlap the entire width of the first signal line in plan view.

2. The imaging device according to claim 1, wherein
the gate of the transistor of the first pixel includes a first portion not overlapping the capacitive element in plan view, and
the first portion of the transistor of the first pixel is electrically coupled to the first signal line.

3. The imaging device according to claim 2, further comprising:
a via in contact with the first portion, wherein
the first portion of the transistor is electrically coupled to the first signal line through the via.

4. The imaging device according to claim 1, further comprising:
a branch signal line, wherein
the branch signal line branches off from the first signal line and extends,
the direction in which the branch signal line extends is different from the direction in which the first signal line extends in plan view, and
the first signal line is electrically coupled to the transistor of the first pixel through the branch signal line.

5. The imaging device according to claim 1, wherein
the capacitive element of the first pixel does not overlap half or more than half of the line width of the first signal line in plan view.

6. The imaging device according to claim 1, wherein
the capacitive element of the first pixel does not overlap the first signal line in plan view.

7. The imaging device according to claim 1, further comprising a plurality of wiring layers positioned above the semiconductor substrate, wherein
the plurality of wiring layers include a first wiring layer and a second wiring layer that are adjacent to each other,
the capacitive element is structured using the first wiring layer, and
the first signal line is included in the second wiring layer.

8. The imaging device according to claim 1, wherein
the maximum length of the capacitive element of the first pixel in the first direction is greater than one third of the length of the first pixel in the first direction in plan view.

9. The imaging device according to claim 1, wherein
when a direction perpendicular to the thickness direction of the semiconductor substrate and the first direction is defined as a second direction, the maximum length of the capacitive element of the first pixel in the first direction is greater than the maximum length of the capacitive element of the first pixel in the second direction in plan view.

10. The imaging device according to claim 1, wherein
the capacitive element of the first pixel includes a first electrode, a second electrode, and an insulating layer between the first electrode and the second electrode.

11. The imaging device according to claim 10, wherein
the first electrode and the second electrode contain metal.

12. The imaging device according to claim 1, wherein
the capacitive element of the first pixel has the largest area in plan view of capacitive elements included in the first pixel.

13. An imaging device comprising:
a semiconductor substrate;
a plurality of pixels arrayed in a first direction on the semiconductor substrate; and
a first signal line positioned above the semiconductor substrate, wherein
each of the plurality of pixels includes:
a photoelectric converter that converts light into signal charges;
a transistor that includes a gate electrically coupled to the first signal line; and
a capacitive element,
in a first pixel of the plurality of pixels,
at least a part of the transistor overlaps the capacitive element in plan view, and
the first signal line does not overlap more than half of the maximum length of the capacitive element in the first direction in plan view.
